(19) United States
(12) Patent Application Publication
(10) Pub. No.: US 2012/0132242 A1
(43) Pub. Date: May 31, 2012

(54) THERMOELECTRIC GENERATOR APPARATUS WITH HIGH THERMOELECTRIC CONVERSION EFFICIENCY

(76) Inventors: Hsu-Shen Chu, Hsinchu City (TW); Jenn-Dong Hwang, Hsinchu City (TW)

(21) Appl. No.: 12/980,954

(22) Filed: Dec. 29, 2010

(30) Foreign Application Priority Data
Nov. 29, 2010 (TW) 99141271

(51) Int. Cl. H01L 35/30

(52) U.S. Cl. 136/205

(57) ABSTRACT

A thermoelectric generator apparatus disposed on a high-temperature surface of an object (as a heat source), at least includes a heat concentrator, a thermoelectric module and a cold-side heat sink. The heat concentrator has a top surface and a bottom surface contacting a high-temperature surface of the object, and an area of the bottom surface is smaller than that of the high-temperature surface. The thermoelectric module is disposed on the top surface of the heat concentrator. The cold-side heat sink is disposed on the thermoelectric module. Heat generated by the heat source is concentrated on the heat concentrator and flows to the hot side of the thermoelectric module for increasing the heat flux (Q′) passing the thermoelectric module and the hot side temperature of the thermoelectric module. Consequently, the thermoelectric conversion efficiency (η) is improved, and the power generation of the thermoelectric module is increased.

This application claims the benefit of Taiwan application Serial No. 099141271, filed Nov. 29, 2010, the subject matter of which is incorporated herein by reference.

### BACKGROUND

1. Technical Field

The disclosure relates in general to a thermoelectric generator apparatus, and more particularly to a thermoelectric generator apparatus with high thermoelectric conversion efficiency.

2. Description of the Related Art

The thermoelectric generator module possesses the characteristics of thermoelectric conversion, that is, converts thermal energy to electrical energy and vice versa. Due to the characteristics of thermoelectric conversion, the thermoelectric generator module can be used in cooling/heating and power generation. When a direct current is applied to a thermoelectric conversion device, heat absorption and heat dissipation will occur to the two ends of the device, and such principle can be used in the cooling/heating technologies. When the two ends of the thermoelectric conversion device are at different temperatures, the thermoelectric conversion device will output a direct current. Thus, the thermoelectric conversion device can be used in the power generation technology.

The thermoelectric generator module is a completely solid state structure, and does not need any motor component. Referring to FIG. 1, a top view of a conventional thermoelectric generator module is shown. A conventional thermoelectric generator module is normally composed of P-type thermoelectric materials 101 and N-type thermoelectric materials 102 which are lump-shaped and electrically cascaded, conductive metal layers 111a and 111b, solders 112a and 112b and top and bottom substrates 121a and 121b which are electrically isolated. The performance of the thermoelectric conversion device is mainly determined by the characteristics of the thermoelectric materials 101 and 102. As indicated in FIG. 1, the P-type thermoelectric materials 101 and the N-type thermoelectric materials 102 are normally vertical type, and are electrically cascaded via the conductive metal layers 111a and 111b, and the top and the bottom substrates 121a/121b, which are electrically isolated, are formed by ceramic substrates for example. When the top and bottom substrates 121a and 121b of the thermoelectric module are at different temperatures (for example, the bottom substrate 121b is at a low temperature and the top substrate 121a is at a high temperature), that is, when the module substrate has temperature difference, the thermoelectric module will generate a direct current in a direction related to the order of the P-type and the N-type thermoelectric materials and the relative position between the cold side and the hot side. In FIG. 1, the direction of the electric current is parallel to the direction of temperature difference and thermal flow.

The power generation efficiency of the thermoelectric module is related to the characteristics of the thermoelectric materials, and the cold/hot side temperatures Tₕₒₜ and T_{Cold} and the temperature difference ΔT of the thermoelectric module. The characteristics of the thermoelectric material are denoted by figure of merit ZT. The thermoelectric conversion efficiency η is expressed as formula (1), and the larger the ZT value of the thermoelectric materials and the temperature difference ΔT between the cold side and the hot side of the thermoelectric module, the higher the thermoelectric conversion efficiency η of the thermoelectric module.

$$Conversion Efficiency \\ {η}_{max} = {\frac{{T}_{hot} - {T}_{cold}}{{T}_{hot}}}^{{ }^{Carnot}} {\frac{\sqrt{1 + ZT} - 1}{\sqrt{1 + ZT} + \frac{{T}_{cold}}{{T}_{hot}}}}^{TE Materials} \qquad ( 1 )$$

The electric power P generated by the thermoelectric module is expressed as formula (2):

P=η×Q (2)

Wherein, η denotes the thermoelectric conversion efficiency, and Q denotes the heat flux passing through the thermoelectric module.

The problem of energy shortage has made the development of renewable energy technologies become an important issue. If the waste heat can be used for the thermoelectric module to generate power by way of temperature difference, then the waste heat is recycled and energy consumption is reduced. The manufacturers are all aiming at increasing the electric power P generated by the thermoelectric module. In formula (2), as long as one of the thermoelectric conversion efficiency η and the heat flux passing through the thermoelectric module Q is increased, the electric power P generated by the thermoelectric module will be increased as well.

### SUMMARY

The disclosure is directed to a thermoelectric generator apparatus, which uses a heat concentrator with high thermal conductivity as a medium disposed between the hot side substrate of a thermoelectric module and a heat source. The heat generated by the heat source is concentrated on the heat concentrator with high efficient thermal conductivity and flows to the hot side of the thermoelectric module for increasing the heat flux (Q′) passing the thermoelectric module and the hot side temperature of the thermoelectric module. Consequently, the thermoelectric conversion efficiency η is improved, and the electric power P generated by the thermoelectric module is increased.

According to a first aspect of the present disclosure, a thermoelectric generator apparatus disposed on a high-temperature surface of an object is provided. The thermoelectric generator apparatus at least includes a heat concentrator, a thermoelectric module and a cold-side heat sink. The heat concentrator has a bottom surface and a top surface, wherein the bottom surface contacts the high-temperature surface of the object, and an area of the bottom surface is smaller than an area of the high-temperature surface. The thermoelectric module is disposed on the top surface of the heat concentrator, and the cold-side heat sink is disposed on the thermoelectric module.

According to a second aspect of the present disclosure, a thermoelectric conversion apparatus including several thermoelectric generator apparatuses as disclosed in the first aspect is provided.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a top view of a conventional thermoelectric generator module;

FIG. 2A˜FIG. 2C respectively show a high temperature object not equipped with any thermoelectric generator apparatus, a high temperature object equipped with an ordinary thermoelectric module, and a high temperature object equipped with an thermoelectric generator apparatus of an embodiment of the disclosure;

FIG. 3 shows a heat concentrator and a thermoelectric module disposed on an outer wall of a high temperature object of an embodiment of the disclosure;

FIG. 4A˜FIG. 4F respectively show various implementations of the heat concentrator of an embodiment of the disclosure;

FIG. 5 shows a thermoelectric generator apparatus of another embodiment of the disclosure;

FIG. 6 shows an installation application of a thermoelectric generator apparatus of an embodiment of the disclosure;

FIG. 7A˜FIG. 7C show an implementation using several thermoelectric generator apparatuses of an embodiment of the disclosure;

FIG. 8A shows a conventional thermoelectric module directly disposed on the outer wall of the heat source;

FIG. 8B shows a thermoelectric generator apparatus of an embodiment of the disclosure disposed on an outer wall of a heat source, wherein the heat concentrator is realized by an aluminum alloy heat collecting block;

FIG. 8C shows another thermoelectric generator apparatus of an embodiment of the disclosure disposed on an outer wall of a heat source, wherein the heat concentrator is realized by an aluminum carbon composite material (MMC) heat collecting block;

FIG. 9 are curves showing temperature change in the cold/hot side of a thermoelectric module of three types of thermoelectric conversion structures under different conditions of cooling water flow rate; and

FIG. 10 are curves showing the generation of electric power of single thermoelectric module of three types of thermoelectric conversion structure under different conditions of cooling water flow rate.

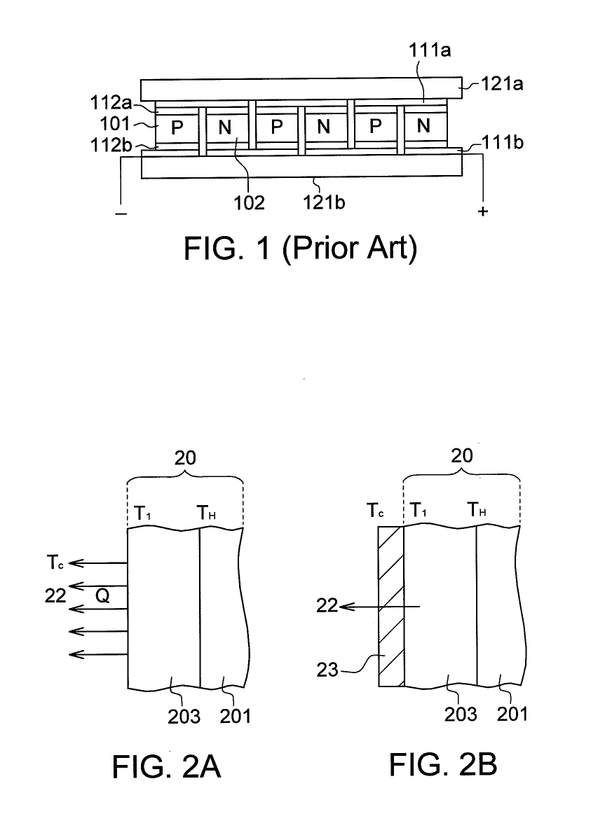

### DETAILED DESCRIPTION

The thermoelectric generator apparatus of the disclosure uses the principle that a direct current is generated when the thermoelectric generator apparatus has two substrates with different temperatures, and has a wide range of application such as power generation by waste heat generated by industrial processes, high temperature exhaust of vehicle or vessel engines, hot springs and terrestrial heat. Take the high temperature furnace commonly used in industrial processes for example. The temperature on the outer wall of the furnace normally ranges between 100˜250° C. When a thermoelectric module is installed on the furnace wall, one substrate of the thermoelectric module directly contacts the furnace wall and serves as a hot side, and the other substrate serves as a cold side by way of air cooling or water cooling. Meanwhile, the cold side and the hot side of the thermoelectric module with temperature difference is capable of generating a direct current. The magnitude of the power generation of the thermoelectric module is determined by three factors, namely, the properties of the P-type and the N-type thermoelectric materials, the temperature difference between the cold side and the hot side of the thermoelectric module, and the heat flux passing through the thermoelectric module.

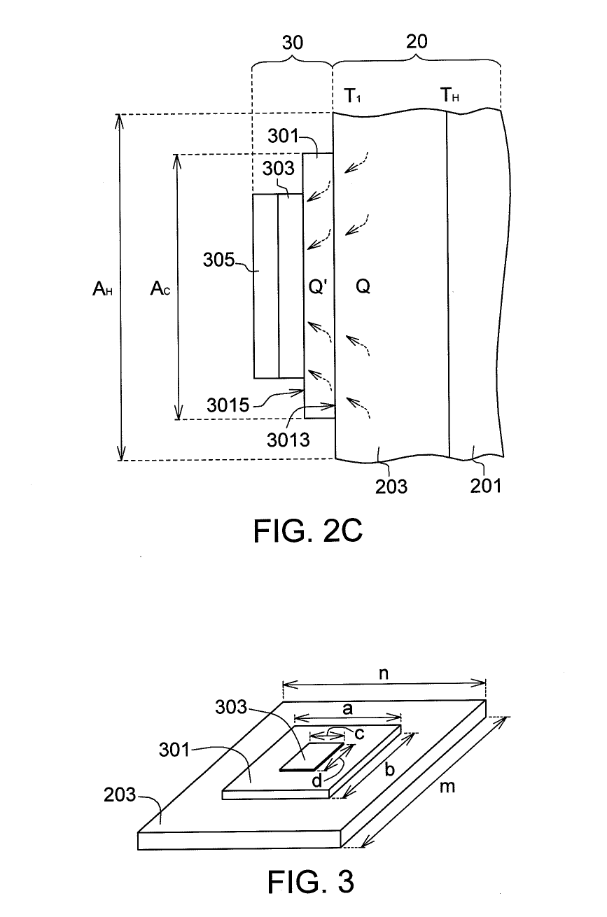

Referring to FIG. 2A˜FIG. 2C, a high temperature object not equipped with any thermoelectric generator apparatus, a high temperature object equipped with an ordinary thermoelectric module, and a high temperature object equipped with an thermoelectric generator apparatus of an embodiment of the disclosure are respectively shown. The high temperature object 20 (such as a high temperature furnace) includes an interior 201 (such as an interior of the high temperature furnace) of the object and an outer wall 203 (such as a high temperature furnace wall) of the object. The temperature of the interior 201 of the high temperature object is denoted by T_{H}, the surface temperature of the outer wall 203 of the high temperature object is denoted by T₁, and the temperature of the air 22 is denoted by T_{C}.

FIG. 2A shows a high temperature object 20 not equipped with any thermoelectric generator apparatus. Meanwhile, the surface temperature T₁ of the outer wall of the high temperature object 203 is a result of the heat flux Q, the temperature T_{H} of the interior 201 of the high temperature object, the coefficient of thermal conductivity of the outer wall of the high temperature object, the coefficient of thermal conductivity of the air, and the environmental temperature T_{C}.

As indicated in FIG. 2B, an ordinary thermoelectric module 23 is installed on the high temperature object 20. The coefficient of thermal conductivity of the thermoelectric module 23 is larger than that of the environmental air 22, and the cold side of the thermoelectric module 23 possibly cooled by a water cooling structure or air-forced convection outdoes the air in terms of heat-absorption. If the heat flux Q is constantly fixed, the surface temperature T₁ of the outer wall 203 of the object will be decreased, making the hot side temperature of the module 23 and the thermoelectric module conversion efficiency decreased. Consequently, the electric power P generated by the module is decreased.

FIG. 2C shows a high temperature object equipped with a thermoelectric generator apparatus of an embodiment of the disclosure. As indicated in FIG. 2C, the thermoelectric generator apparatus 30 of an embodiment of the disclosure includes a heat concentrator 301, a thermoelectric module 303 and a cold-side heat sink 305. The heat concentrator 301 possesses high thermal conductivity, and has a coefficient of thermal conductivity ranged between 100˜1000 W/mK. The heat concentrator 301 has a bottom surface 3013 and a top surface 3015, wherein the bottom surface 3013 contacts the high-temperature surface of the object 20 (such as the surface of the outer wall 203 of the object), and a bottom surface area A_{C} of the bottom surface 3013 is smaller than an area of the high-temperature surface A_{H} of the object 20. The thermoelectric module 303 is disposed on the top surface 3015 of the heat concentrator 301. The cold-side heat sink 305 is disposed on the thermoelectric module 303 for discharging heat.

The heat flux Q transmitted from the interior 201 of the high temperature object 20 via the outer wall 203 of the object is constant, and the heat concentrator 301 possesses high thermal conductivity, wherein the bottom surface area A_{C} of the heat concentrator 301 is smaller than a surface area A_{H} of the surface of the high temperature object 20. As the thermal flow can be quickly concentrated on the heat concentrator 301 whose area is smaller, the heat flux of the said region is increased to Q′ (that is, Q′>Q) due to the decrease in area. Due to the increase in the heat flux, the outer wall of the high temperature object 203 can maintain or even increase the hot side temperature T_{H}, thereby improving the thermoelectric conversion efficiency η. Accordingly, the installation structure disclosed in an embodiment of the disclosure for concentrating the heat is implemented by combining the thermoelectric module 303 and the heat concentrator 301, the heat flux passing through the thermoelectric module as well as the thermoelectric conversion efficiency η can be increased. According to the equation P=Q′×η which expresses the power generation of the thermoelectric module, the electric power P generated by the thermoelectric module will significantly increase as well if Q′ and η both increase.

FIG. 3 shows a heat concentrator and a thermoelectric module disposed on an outer wall of a high temperature object of an embodiment of the disclosure. In the practical application, several thermoelectric generator apparatuses 30 of an embodiment of the disclosure can be arranged on the outer wall of a high temperature object 203 separately. For example, each thermoelectric generator apparatus 30 is installed within a fix-sized area (as a unit) on the outer wall 203, and the size of the fix-sized area could be determined according to the heat flux Q of the outer wall 203. The heat concentrator 301 is formed by a material with high thermal conductivity, while the suitable size of the area of the heat concentrator 301 is determined according to the factors including the heat flux Q, the coefficient of thermal conductivity of the material for forming the heat concentrator 301 and the size of the thermoelectric module 303, wherein the suitable size of the area of the heat concentrator 301 should be ranged between the fix-sized area of the heat source and the area of the thermoelectric module 303. As indicated in FIG. 3, the area (a×b) of the heat concentrator 301 is smaller than a fix-sized area (m×n) of the outer wall 203 but larger than the area (c×d) of the thermoelectric module 303.

In an embodiment, the heat concentrator 301 can be a heat collecting block integrated as one piece, or multiple heat collecting blocks stacked vertically. When the heat concentrator 301 is one-piece heat collecting block, the area of the bottom surface can be identical to the area of the top surface as indicated in the heat collecting block of FIG. 2C, or the area of the bottom surface can be larger than the area of the top surface. When the heat concentrator 301 is realized by multiple heat collecting blocks stacked vertically, the cross-section of the heat collecting blocks diminishes with the height of the stacked heat collecting blocks. Regardless the number of the heat collecting block being one or plural, the shape of the heat collecting block is not subjected to any specific restriction. In one embodiment, the heat concentrator 301 can be realized by one single or multiple heat collecting blocks stacked vertically as long as the cross-section of the heat concentrator 301 diminishes with the height.

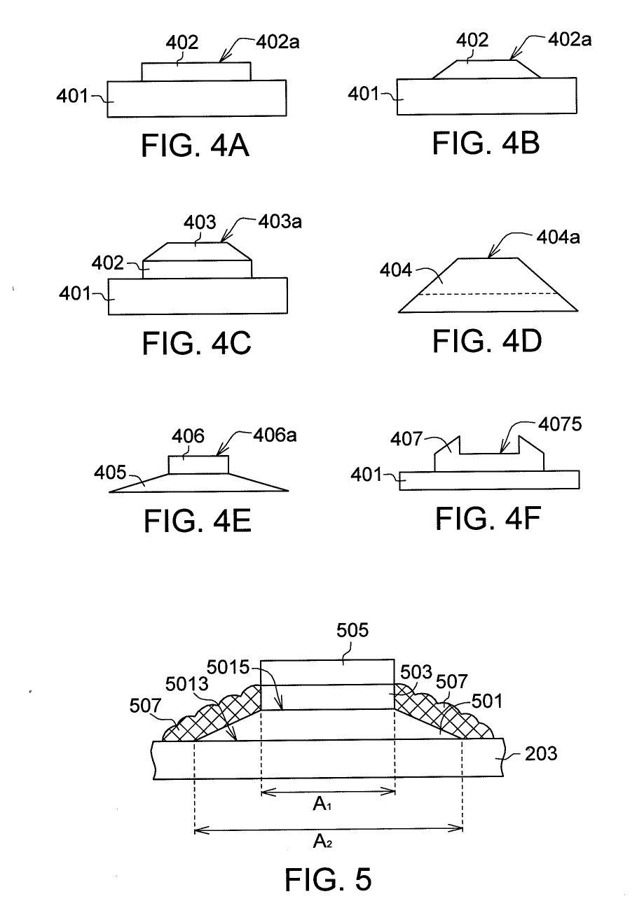

Referring to FIG. 4A˜FIG. 4F, various implementations of the heat concentrator of an embodiment of the disclosure are respectively shown. As indicated in FIG. 4A, the heat concentrator includes a first heat collecting block 401 and a second heat collecting block 402 both are plate-shaped, wherein the cross-section of the first heat collecting block 401 is larger than that of the second heat collecting block 402, and the thermoelectric module is disposed on the top surface 402a of the second heat collecting block 402. As indicated in FIG. 4B, the heat concentrator includes a plate-shaped first heat collecting block 401 and a trapezoidal second heat collecting block 402, wherein the cross-section of the second heat collecting block 402 is smaller than that of the first heat collecting block 401, and the thermoelectric module is disposed on the top surface 402a of the second heat collecting block 402. The heat concentrator of FIG. 4C includes a first heat collecting block 401 and a second heat collecting block 402 both being plate-shaped, and a trapezoidal third heat collecting block 403, wherein the cross-section of the first heat collecting block 401 is larger than that of the second heat collecting block 402, and an area of the top surface 403a of the third heat collecting block 403 on which the thermoelectric module is disposed is smaller than the cross-section of the second heat collecting block 402. The heat concentrator of FIG. 4D includes a trapezoidal heat collecting block 404, and an area of the top surface 404a on which the thermoelectric module is disposed is smaller than that of the bottom surface. Alternatively, the heat collecting block 404 can be realized by two independent trapezoidal heat collecting blocks stacked together. The heat concentrator of FIG. 4E includes a trapezoidal first heat collecting block 405 and a platform-shaped second heat collecting block 406, wherein the thermoelectric module is disposed on the top surface 406a of the second heat collecting block 406. The heat concentrator of FIG. 4F includes a plate-shaped first heat collecting block 401 and an irregular-shaped second heat collecting block 407, wherein the second heat collecting block 407 has a notch 4075 for setting the thermoelectric module.

In the above embodiment, the heat concentrator can be formed by multiple block heat collecting block stacked together. However, the one-piece heat collecting block can be formed in the same shape as the multiple stacked heat collecting blocks indicated in FIG. 4A˜FIG. 4C and FIG. 4E˜FIG. 4F, so that the cross-section of the single heat concentrator also diminishes with the height.

Moreover, anyone who is skilled in the technology of the disclosure would understand that the plate with a squared platform or the plate with a trapezoidal platform, the trapezoidal plate or a combination thereof as shown in FIG. 4A˜FIG. 4F are merely examples of many possible implementations. In the disclosure, the shape of the heat collecting block is not limited to the shapes exemplified above, and can be combined with other shapes such as semi-circle and irregular shape in addition to the combination of plate, small platform, and trapezoid, and any geometric shapes contacting the heat source by a larger area but contacting the module by a smaller area for reducing the area and intensifying the heat flux will do.

Despite each set of heat concentrator 301 formed by the heat collecting blocks is used by a thermoelectric module 303 as indicated in FIG. 2C and FIG. 3, the disclosure is not limited thereto. Each set of heat concentrator 301 formed by the heat collecting block(s) can also be used by multiple thermoelectric generator modules. For example, several platforms formed on the top surface of one heat concentrator are respectively jointed to several thermoelectric modules.

In an embodiment of the disclosure, the heat concentrator 301 is formed by a material with high thermal conductivity, such as metal, alloy thereof, metal base composite material, and carbon material such as graphite. Examples of metals and alloy thereof include copper, aluminum, silver, zinc, magnesium, titanium, and alloy thereof. Examples of metal base composite materials include copper base, aluminum base and silver base composite materials. Examples of the second phase of the base material of the metal base composite material include ceramic particles (such as SiC, AlN, BN, Si₃N₄ . . . ), diamond powder, and various forms of carbon fiber and graphite foam.

Additionally, in an embodiment of the disclosure, the junction between the outer wall of the high temperature object 203 (that is, the heat source) and the heat concentrator 301, the junction among multiple heat collecting blocks, and the junction between the heat concentrator 301 and the thermoelectric module 303 can be applied with suitable interface materials such as heat conducting paste for reducing the thermal resistance in the course of junction.

In an embodiment of the disclosure, the cold-side heat sink 305 can be realized by a high surface area metal fin or foam either equipped with or without a fan, a metal block containing cooling liquid inside, or other device capable of dissipating the heat quickly. If a fan is selectively disposed on the cold-side heat sink 305, and the cold-side heat sink is realized by large surface area metal fins or large surface area foams, the heat-dissipation efficiency will thus be increased.

FIG. 5 shows a thermoelectric generator apparatus of another embodiment of the disclosure. In the present embodiment as indicated in FIG. 5, the thermoelectric generator apparatus includes a heat concentrator 501, a thermoelectric module 503, a cold-side heat sink 505 and an insulation material layer 507. The heat concentrator 501 with high thermal conductivity is a trapezoid having a bottom surface 5013 and a top surface 5015, wherein an area A₁ of the top surface 5015 is smaller than an area A₂ of the bottom surface 5013, and the bottom surface 5013 contacts the high temperature object surface (such as the surface of the outer wall 203 of the object). The thermoelectric module 503 is disposed on the top surface 5015 of the heat concentrator 501. The cold-side heat sink 505 is disposed on the thermoelectric module 503. The insulation material layer 507 is disposed on the high-temperature surface of the object (such as on the surface of the outer wall 203 of the object) and covers the heat concentrator 501 to avoid the dissipation of the heat and maintain the temperature at the hot side of the thermoelectric module 503. Examples of the insulation material layer 507 include a ceramic material layer with low thermal conductivity, a thermal insulation cotton layer and a porous material. The ceramic material layer with low thermal conductivity could be formed by the spraying process. The thermal insulation cotton layer or the porous material, which contains such as asbestos and glass fiber and so on, can be formed by way of covering. For example, the insulation material layer 507 may cover two sides of the thermoelectric module 503 (as shown in FIG. 5), or cover two sides of the heat concentrator 501 but expose the top surface 5015 of the heat concentrator 501.

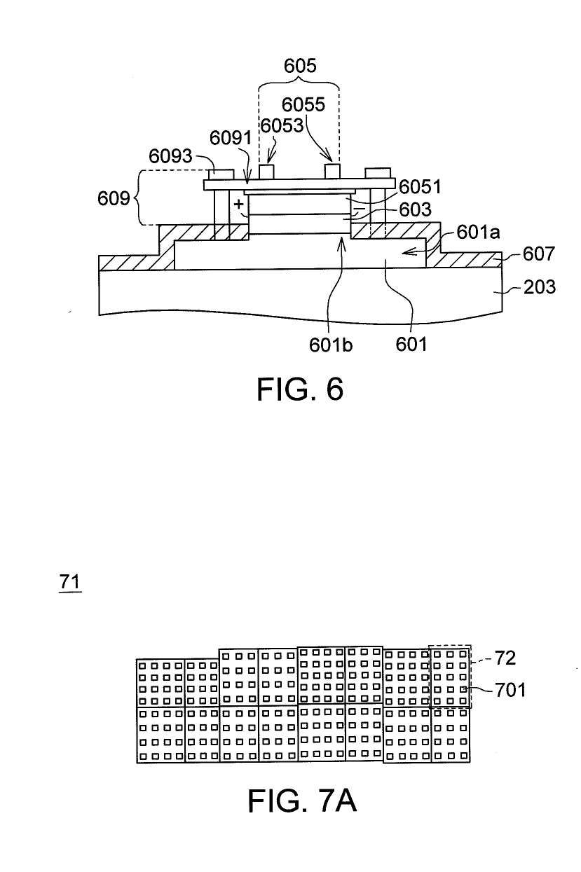

FIG. 6 shows an installation application of a thermoelectric generator apparatus of an embodiment of the disclosure. When the thermoelectric generator apparatus of an embodiment of the disclosure is used in practical installation, the thermoelectric generator apparatus may further include a securing assembly for fixing the related elements onto the surface of a high temperature object (such as the outer wall of the high temperature object 203). According to one of the installation structures indicated in FIG. 6, the thermoelectric generator apparatus includes a heat concentrator 601, a thermoelectric module 603, a cold-side heat sink 605, an insulation material layer 607 and a securing assembly 609, wherein the heat concentrator 601 includes a first high thermal conductivity heat collecting block 601a and a second high thermal conductivity heat collecting block 601b. The first high thermal conductivity heat collecting block 601a directly contacts the heat source, and the second high thermal conductivity heat collecting block 601b is a small protruded platform disposed on the first high thermal conductivity heat collecting block 601a, wherein the heat source is such as the outer wall of the high temperature object 203. In one application, the height and the area of the bottom surface of the small protruded platform are about 1 mm and 3 cm×3 cm (=9 cm²), respectively. The thermoelectric module 603 is disposed on the second high thermal conductivity heat collecting block 601b. The second high thermal conductivity heat collecting block 601b has a small protruded platform, and can be designed to have the same area with the thermoelectric module 603 for intensifying the effects of heat concentration and increase of the heat flux. In the present application example, the first high thermal conductivity heat collecting block 601a and the second high thermal conductivity heat collecting block 601b are integrally formed as one piece.

The cold-side heat sink 605, can be realized by such as a heat sink made from a metal block containing cooling liquid inside, includes a metal block (such as a copper block) with cooling water channel 6051, a cooling water inlet 6053, and a cooling water outlet 6055. The application as illustrated in FIG. 6 also has an insulation material layer 607 covering the heat concentrator 601 to avoid the heat dissipation and maintain the temperature at the hot side of the thermoelectric module 603.

In the application as illustrated in FIG. 6, the securing assembly 609 includes a fixing piece 6091 and a screw-fastening member 6093. The fixing piece 6091 is disposed on the cold-side heat sink 605 (such as on cooling metal block 6051), and the screw-fastening member 6093 (such as a screw) passes through the fixing piece 6091 for fixing the thermoelectric generator apparatus onto the outer wall of the high temperature object 203. Meanwhile, the cold-side heat sink 605, the thermoelectric module 603, and the heat concentrator 601 receive a downward pressure by the fixing piece 6091. In the present application, the screw-fastening member 6093, in addition to the way of passing through the fixing piece 6091, can also selectively pass through the heat concentrator 601 to be fixed at the outer wall of the high temperature object 203. Alternatively, the bottom of the screw-fastening member can be jointed to the surface of the heat concentrator 601, wherein the bottom surface of the heat concentrator 601 can be formed by suitable interface material such as heat conducting paste for jointing the outer wall of the high temperature object 203. The fixing method depends on actual situations, and the disclosure does not impose specific restrictions.

In the above embodiments, one thermoelectric generator apparatus is exemplified for detailed explanations. However, in practical application, more than one set of thermoelectric generator apparatus can be used to fit actual needs. One of the application implementations using multiple sets of thermoelectric generator apparatus is exemplified below.

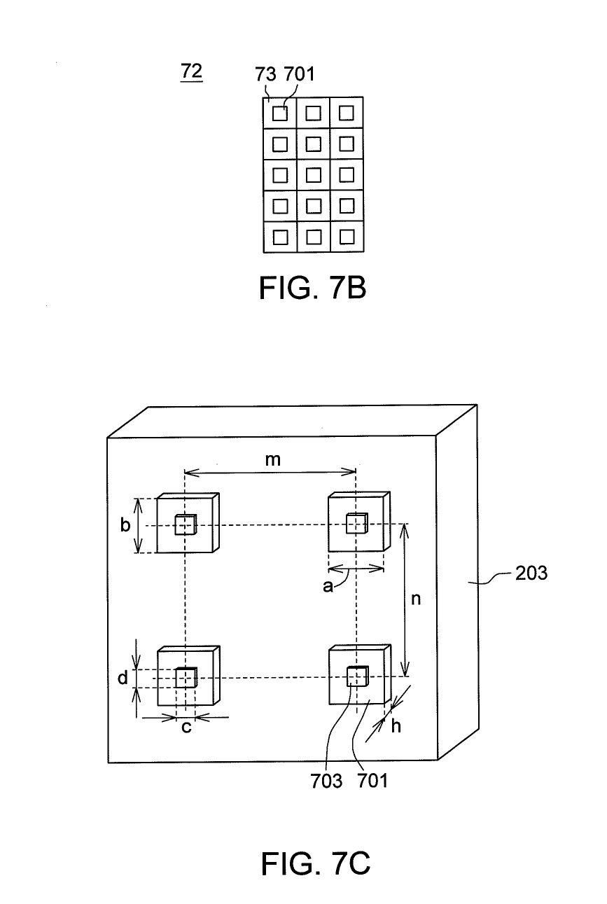

Referring to FIG. 7A˜FIG. 7C, an implementation using several thermoelectric generator apparatuses of an embodiment of the disclosure is shown. Examples of heat sources include the outer side of the high temperature furnace wall and the exhaust wall. Based on the actual conditions of the heat source, such as the temperature and the heat flux, the heat source could be divided into one or several virtual regions. As indicated in FIG. 7A, the thermoelectric conversion apparatus of an embodiment of the disclosure includes a plurality of thermoelectric generator apparatuses, and the thermoelectric generator apparatuses are disposed on the high-temperature surface of the object (the heat source) and arranged as an m×n matrix, in view of a full region 71 and a unit region 72. Also, two adjacent thermoelectric generator apparatuses are disposed separately, and m and n can be two identical or different positive integers. However, the matrix arrangement is merely one of many applicable arrangements, and the disclosure is not limited to the matrix arrangement. Moreover, two adjacent thermoelectric generator apparatuses can be connected or separated, and the disclosure does not impose further restriction specifically.

FIG. 7B shows an enlargement of a region of FIG. 7A. FIG. 7C is a partial enlargement of FIG. 7B. As indicated in FIG. 7B, the thermoelectric conversion apparatus within a unit region 72 is exemplified by several thermoelectric generator apparatuses arranged in a 5×3 matrix. In FIG. 7B, the unit region 72 is further divided into 5×3 sub-regions 73, and each sub-region 73 has a thermoelectric generator apparatus (such as including a heat concentrator 701, a thermoelectric module and a cold-side heat sink). Please refer to FIG. 2C, FIG. 3 and FIG. 5 and related descriptions for the structural details of each thermoelectric generator apparatus, and FIG. 6 for the installation method.

As indicated in FIG. 7C, in practical application, the heat concentrator 701 formed by metal or metal base composite material (such as aluminum carbon composite material) can be tightly disposed on the outer wall of a high temperature object 203 (that is, the outer side of a heat source such as the high temperature furnace wall or the exhaust wall). The size of heat concentrator 701 ranges between the area of the sub-region 73 of the heat source and the area of the thermoelectric module 703. In an application, the width of the entire heating furnace wall is about 10 m, the height is about 3 m, and the surface can be divided into many regions, wherein each region of 18.2 cm×19.3 cm can have a set of heat concentrator 701 and a thermoelectric module 703 disposed therein, and the heat concentrator 701 can be realized by one single heat collecting block whose area is about 8 cm×8 cm and thickness is about 5 mm. The above dimensions are for reference only, not for limiting the scope of protection of the disclosure. Anyone who is skilled in the technology of the disclosure would understand that the above designs can be adjusted or modified to fit actual needs.

### <Experiments Related to Thermoelectric Generator Apparatus>

Experiments on three types of thermoelectric generator apparatus structure are performed below under the same conditions of the heat source temperature and the heat flux in relation to the structure without heat collecting block (conventional thermoelectric module), the structure with a heat collecting block formed by aluminum alloy and the structure with heat collecting block formed aluminum carbon composite material (the thermoelectric generator apparatus of the embodiment). In the experiments, a cooling copper block (that is, the cold-side heat sink of the embodiment) is disposed on each thermoelectric module, and temperature difference at the cold/hot side and the generated electric power are measured under different conditions of cooling water flow rate.

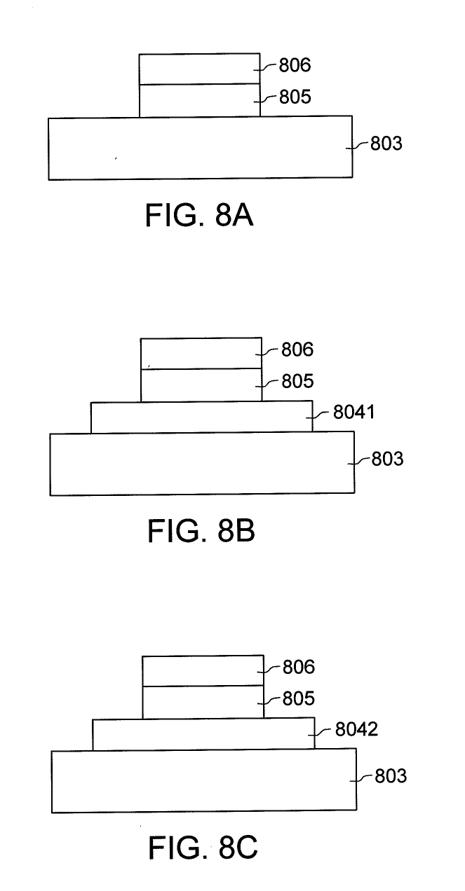

FIG. 8A shows a conventional thermoelectric module directly disposed on the outer wall of the heat source. A thermoelectric module 805 and a water cooling copper block 806 are disposed on the outer wall of the heat source 803. FIG. 8B shows a thermoelectric generator apparatus of an embodiment of the disclosure disposed on an outer wall of a heat source, wherein the heat concentrator is realized by an aluminum alloy heat collecting block 8041. FIG. 8C shows another thermoelectric generator apparatus of an embodiment of the disclosure disposed on an outer wall of a heat source, wherein the heat concentrator is realized by an aluminum carbon composite material (MMC) heat collecting block 8042.

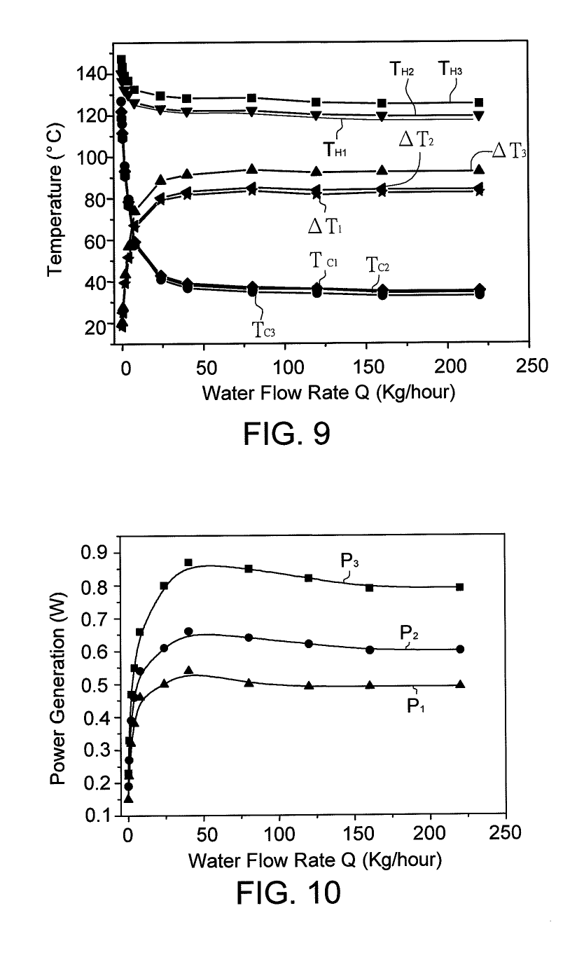

FIG. 9 are curves showing temperature change in the cold/hot side of a thermoelectric module of three types of thermoelectric conversion structures under different conditions of cooling water flow rate. Curve Tₕ₁ indicates the hot side temperature of the thermoelectric module (FIG. 8A) not equipped with any heat collecting block. Curve T_{c1} denote the cold side temperature curve of the thermoelectric module (FIG. 8A) not equipped with any heat collecting block. Curve ΔT₁ indicates cold/hot side temperature difference of the thermoelectric module (FIG. 8A) not equipped with any heat collecting block. Curve Tₕ₂ indicates the hot side temperature of the thermoelectric module (FIG. 8B) equipped with aluminum alloy heat collecting block 8041. Curve T_{c2} indicates the cold side temperature of the thermoelectric module (FIG. 8B) equipped with aluminum alloy heat collecting block 8041. Curve ΔT₂ indicates the cold/hot side temperature difference of the thermoelectric module (FIG. 8B) equipped with aluminum alloy heat collecting block 8041. Curve Tₕ₃ indicates the hot side temperature of the thermoelectric module (FIG. 8C) equipped with MMC heat collecting block 8042. Curve T_{c3} indicates the cold side temperature of the thermoelectric module (FIG. 8C) equipped with MMC heat collecting block 8042. Curve ΔT₃ indicates the cold/hot side temperature difference of the thermoelectric module (FIG. 8C) equipped with MMC heat collecting block 8042.

As indicated in FIG. 9, the results shows that when the structure is equipped with heat collecting blocks regardless being the aluminum alloy heat collecting block or the MMC heat collecting block, the cold/hot side temperature difference ΔT₂ and ΔT₃ of the thermoelectric module are both larger than the cold/hot side temperature difference ΔT₁ of the thermoelectric module not equipped with any heat collecting block. Moreover, since the coefficient of thermal conductivity of the aluminum carbon metal base composite material (MMC) is higher than that of the aluminum alloy, the hot side temperature of the thermoelectric module with MMC is even higher (Tₕ₃>Tₕ₂), and the cold/hot side temperature difference of the thermoelectric module is further widened, so that the temperature difference ΔT₃ is larger than the temperature difference ΔT₂.

FIG. 10 are curves showing the generation of electric power of single thermoelectric module of three types of thermoelectric conversion structure under different conditions of cooling water flow rate. Curve P₁ indicates the power generation of the thermoelectric module (FIG. 8A) not equipped with any heat collecting blocks. Curve P₂ indicates the power generation of the thermoelectric module (FIG. 8B) equipped with aluminum alloy heat collecting block. Curve P₃ indicates the power generation of the thermoelectric module (FIG. 8C) equipped with MMC heat collecting block. The results of FIG. 10 also show that the heat collecting block significantly increase the power generation of the thermoelectric module. When the power generation structure is not equipped with any heat collecting blocks (FIG. 8A), the maximum electric power generated by one single thermoelectric module is about 0.54 W. When the power generation structure is equipped with aluminum alloy heat collecting blocks (FIG. 8B), the maximum electric power generated by one single thermoelectric module is increased to about 0.66 W. When the power generation structure is equipped with aluminum carbon composite material heat collecting blocks (FIG. 8C), the maximum electric power generated by one single thermoelectric module is increased to about 0.88 W, which is 63% higher than the power generation structure not equipped with any heat collecting blocks.

According to the aforementioned description, the thermoelectric generator apparatus of the embodiments uses the heat concentrator with high thermal conductivity, such as metal or metal base composite material with high thermal conductivity and high thermal diffusivity, as a medium between the hot side substrate of the thermoelectric module and the heat source. The heat generated by the heat source is concentrated on the heat concentrator with high efficient thermal conductivity and flows to the hot side of the thermoelectric module for increasing the heat flux (Q′) passing the thermoelectric module and the hot side temperature of the thermoelectric module. Consequently, the thermoelectric conversion efficiency η is improved. Thus, both the heat flux Q′ and the thermoelectric conversion efficiency η of the thermoelectric generator apparatus of the embodiment of the disclosure are increased, and the electric power (P=Q′×η) generated by the thermoelectric module will be increased significantly. Related experiments also show that both the electric power generation and the thermoelectric conversion efficiency of the thermoelectric conversion module of the embodiments of the disclosure do increase. In the embodiments of the disclosure, the heat concentrator can be realized in a geometric shape with diminishing cross-section. For example, the heat concentrator includes several heat collecting blocks stacked together with diminishing cross-section or one single heat collecting block with diminishing cross-section for further increasing the heat flux passing the thermoelectric module and the power generation of the thermoelectric module.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A thermoelectric generator apparatus, disposed on a high-temperature surface of an object, and the thermoelectric generator apparatus comprising:
a heat concentrator having a bottom surface and a top surface, the bottom surface contacting the high-temperature surface of the object, and an area of the bottom surface smaller than an area of the high-temperature surface;
a thermoelectric module disposed on the top surface of the heat concentrator; and
a cold-side heat sink disposed on the thermoelectric module.

2. The thermoelectric generator apparatus according to claim 1, wherein a cross-section of the heat concentrator diminishes with the height of the heat concentrator.

3. The thermoelectric generator apparatus according to claim 1, wherein the top surface of the heat concentrator has a platform jointed to the thermoelectric module.

4. The thermoelectric generator apparatus according to claim 1, wherein the heat concentrator is a heat collecting block integrated as one piece, and an area of the bottom surface of the heat collecting block is larger than an area of the top surface.

5. The thermoelectric generator apparatus according to claim 1, wherein the heat concentrator comprises a plurality of heat collecting blocks stacked vertically, and the cross-section of the heat collecting blocks diminishes with the height of the stacked heat collecting blocks.

6. The thermoelectric generator apparatus according to claim 1, wherein the coefficient of thermal conductivity of the heat concentrator ranges between 100˜1000 W/mK and the material of the heat concentrator comprises metal, alloy thereof, metal base composite material or carbon material.

7. The thermoelectric generator apparatus according to claim 6, wherein the material of the heat concentrator comprises copper, aluminum, silver, zinc, magnesium, titanium or alloy thereof, and metal base composite material comprises copper base, aluminum base, silver base composite material, or graphite sheet, and a second phase of the base material of the metal base composite material comprises ceramic particles, diamond powder, and various forms of carbon fiber or graphite foam.

8. The thermoelectric generator apparatus according to claim 1, further comprising:
an insulation material layer disposed on the high-temperature surface of the object for covering the heat concentrator, wherein the insulation material layer is a ceramic material layer with low thermal conductivity, a thermal insulation cotton layer, or made of a porous material.

9. The thermoelectric generator apparatus according to claim 1, wherein the cold-side heat sink is a metal fin with large surface area, a foam with large surface area, or a metal block containing cooling liquid inside.

10. The thermoelectric generator apparatus according to claim 1, further comprising a securing assembly, wherein the securing assembly comprises:
a fixing piece disposed on the cold-side heat sink; and
a screw-fastening member passing through the fixing piece, and the fixing piece applying a downward pressure onto the cold-side heat sink, the thermoelectric module and the heat concentrator, and the screw-fastening member being fixed onto the high-temperature surface of the object.

11. A thermoelectric conversion apparatus, comprising:
a plurality of thermoelectric generator apparatuses, each thermoelectric generator apparatus at least comprising:
a heat concentrator having a bottom surface and a top surface, wherein the bottom surface contacts the high-temperature surface of the object, and an area of the bottom surface is smaller than an area of the high-temperature surface;
a thermoelectric module disposed on the top surface of the heat concentrator; and
a cold-side heat sink disposed on the thermoelectric module.

12. The thermoelectric conversion apparatus according to claim 11, wherein the thermoelectric generator apparatuses are arranged as a matrix on the high-temperature surface of the object.

13. The thermoelectric conversion apparatus according to claim 11, wherein the adjacent thermoelectric generator apparatuses disposed on the high-temperature surface of the object are spaced apart from each other.

14. The thermoelectric conversion apparatus according to claim 11, wherein the top surface of the heat concentrator of each thermoelectric generator apparatus has a platform jointed to the thermoelectric module.

15. The thermoelectric conversion apparatus according to claim 11, wherein the heat concentrator of each thermoelectric generator apparatus is a heat collecting block integrated as one piece, and an area of the bottom surface of the heat collecting block is larger than an area of the top surface.

16. The thermoelectric conversion apparatus according to claim 11, wherein the heat concentrator of each thermoelectric generator apparatus comprises a plurality of heat collecting blocks stacked vertically, and the cross-section of the heat collecting blocks diminishes with the height of the stacked heat collecting blocks.

17. The thermoelectric conversion apparatus according to claim 11, wherein the heat concentrator of each thermoelectric generator apparatus has a coefficient of thermal conductivity ranged between 100˜1000 W/mK, and the material of the heat concentrator comprises metal, alloy thereof, metal base composite material or carbon material.

18. The thermoelectric conversion apparatus according to claim 17, wherein the material of the heat concentrator of each thermoelectric generator apparatus comprises copper, aluminum, silver, zinc, magnesium, titanium or alloy thereof, and metal base composite material comprises copper base, aluminum base, silver base composite material, or graphite sheet, and a second phase of the base material of the metal base composite material comprises ceramic particles, diamond powder, and various forms of carbon fiber or graphite foam.

19. The thermoelectric conversion apparatus according to claim 11, wherein each thermoelectric generator apparatus further comprises:
an insulation material layer disposed on the high-temperature surface of the object for covering the heat concentrator, wherein the insulation material layer is a ceramic material layer with low thermal conductivity, a thermal insulation cotton layer, or made of a porous material.

20. The thermoelectric conversion apparatus according to claim 11, wherein the cold-side heat sink of each thermoelectric generator apparatus is a metal fin with large surface area, a foam with large surface area, or a metal block containing cooling liquid inside.

21. The thermoelectric conversion apparatus according to claim 11, wherein each thermoelectric generator apparatus further comprises a securing assembly, and the securing assembly comprises:
a fixing piece disposed on the cold-side heat sink; and
a screw-fastening member passing through the fixing piece, and the fixing piece applying a downward pressure onto the cold-side heat sink, the thermoelectric module and the heat concentrator, and the screw-fastening member being fixed onto the high-temperature surface of the object.
